(19) United States
(12) Patent Application Publication
(10) Pub. No.: US 2019/0131984 A1
(43) Pub. Date: May 2, 2019

(54) MICRO-RESONATOR-BASED FREQUENCY COMB TERAHERTZ ION CLOCK

(71) Applicant: Lockheed Martin Corporation, Bethesda, MD (US)

(72) Inventors: Christopher E. Langer, Highlands Ranch, CO (US); John P. Gaebler, Golden, CO (US); Brian Neyenhis, Highlands Ranch, CO (US)

(73) Assignee: Lockheed Martin Corporation, Bethesda, MD (US)

(21) Appl. No.: 15/796,710

(22) Filed: Oct. 27, 2017

(51) Int. Cl. H03L 7/26; H03B 17/00; H01S 3/227; H01S 3/10; H01S 3/06

(52) U.S. Cl. CPC H03L 7/26; H03B 17/00; H01S 3/227; H03B 2200/0084; H01S 3/06; H03B 2200/0044; H01S 3/10061

(57) ABSTRACT

An ion-based atomic clock comprising an ion trap configured to trap a plurality of ions; and a micro-resonator-based frequency comb configured to directly drive a terahertz transition between metastable levels in the trapped plurality of ions. The micro-resonator-based frequency comb may be configured to directly drive a 24 terahertz transition in at least one Ba⁺ ion, a 8.4 terahertz transition in at least one Sr⁺ ion, or a 1.8 terahertz transition in at least one Ca⁺ ion. The micro-resonator-based frequency comb may be configured to provide output similar to a pulsed laser. The ion-based atomic clock may be free of a carrier-offset-stabilized frequency comb. The ion-based atomic clock may comprise a mini-vacuum ion trap assembly. Polarization of the micro-resonator-based frequency comb may be tuned to make the ion-based atomic clock be insensitive to laser light power fluctuations.

### BACKGROUND

Communications, finance, navigation, and location determination systems frequently use timing for various purposes. For example, timing can be critical for frequency and time standards for Internet applications, for radioastronomy interferometry, for high-frequency trading, and for mobile location services.

### SUMMARY

Some aspects include an ion-based atomic clock comprising an ion trap configured to trap a plurality of ions, and a micro-resonator-based frequency comb configured to directly drive a terahertz transition between metastable levels in the trapped plurality of ions.

Additional aspects include a micro-resonator-based frequency comb configured to directly drive a terahertz transition between metastable levels in a trapped plurality of ions.

Further aspects include a method comprising trapping a plurality of ions, and directly driving a terahertz transition between metastable levels in the trapped plurality of ions using a micro-resonator-based frequency comb.

### BRIEF DESCRIPTION OF DRAWINGS

FIG. 1 is a plan view of exemplary components of an exemplary atomic clock apparatus 100, in accordance with some embodiments.

FIG. 2 is a perspective view of exemplary components of an exemplary atomic clock apparatus 100, in accordance with some embodiments.

FIG. 3 is a perspective view of an exemplary ion trap 110, in accordance with some embodiments.

FIG. 4 is a flow chart of an exemplary method 400 of operation of an exemplary atomic clock apparatus, in accordance with some embodiments.

### DETAILED DESCRIPTION

The inventors have recognized and appreciated that timing is almost entirely reliant on global positioning system (GPS) signals, which may be extremely vulnerable to interference, including jamming and spoofing. GPS signals may also be unavailable or unreliable in certain environments and situations. For example, relying on GPS signals may not be possible or advisable undersea, underground, in deep space, in urban environments, within dense foliage, and/or in jammed areas.

The inventors have also recognized and appreciated that timing may be critical in numerous applications including but not limited to communications (such as mobile networks), finance (such as time stamping for high frequency trading), navigation, and location determination systems (including power grid failure determination), and that at least some of these applications may be better served by systems that do not rely so much on GPS. Additional applications in which timing is critical include scientific applications, such as tests for changes in fundamental constants, measurements of planetary geodesy or gravimetry, investigations of universe symmetry violations, laboratory instrument calibration, and seismic epicenter location determination. Moreover, the inventors have recognized and appreciated that precision timing may be essential for inertial navigation systems operating in the absence of GPS, as well as for GPS receivers operating in areas with noisy or intermittent GPS readings.

The inventors have recognized and appreciated that generating timing locally on a receiving platform may reduce or eliminate the reliance on GPS signals for timing. While clocks have been used to generate timing locally, the inventors have recognized and appreciated that previous clocks have been either far too large, heavy, and/or power-hungry to use on a receiving platform or far too inaccurate or unstable to be usable for many demanding applications. For example, low size, weight, and power (SWaP) microwave neutral atom clocks based on small vapor cells have been developed and are called Chip Scale Atomic Clocks (CSAC). CSAC devices (such as compact Cs and Rb clocks) have instability (at 1 second integration duration) of 3.5*10⁻¹⁰, long term aging of 9*10⁻¹⁰/month, and maximum frequency change of 5*10⁻¹⁰ over an operating temperature range of −10° C. to +35° C. CSAC devices may have inaccuracy of 10⁻¹⁰ While low SWaP, the stability and accuracy of CSAC devices may be 10⁻⁴ that of some embodiments herein and 1*10⁻⁸ that of laboratory grade optical clocks. Moreover, CSAC devices may rely on vapor cells that are very sensitive to environmental temperature and display aging. CSAC devices may also require extensive (e.g., 6-12 hours) calibration after turn-on and may be limited to mission durations of 3-6 hours due to temperature sensitivity and aging. On the other hand, higher precision Cs and Rb clocks such as those commercially available may provide improved accuracy and stability (e.g., 5*10⁻¹³ inaccuracy and 5*10⁻¹² instability), but at the cost of significantly higher size, weight, and power (e.g., these devices may have a volume of approximately 10 liters, while CSAC devices may have a volume of approximately 20 cubic centimeters).

Additionally, while laboratory-grade Cs/Rb fountain clocks may be considered the world standard for time keeping, they are far higher SWaP than CSAC devices and not fieldable. For example, they may have 10⁻¹⁶ inaccuracy and 10⁻¹³ instability, but their volume may be approximately 100 liters. Similarly, laboratory optical clocks are considered the most accurate clocks (e.g., they may have 10⁻¹⁸ inaccuracy and 10⁻¹⁶ instability), but they are also not fieldable given their similarly high volume and reliance on many high precision lasers and large ultra-stable cavities. Moreover, the inventors have recognized and appreciated that these laboratory clocks may have no reasonable path to miniaturization to make them fieldable. The inventors have recognized and appreciated that timing may be generated locally by a clock that is more accurate, more stable, and lower in size, weight, and power (SWaP) than previous clocks, including those described above.

The inventors have recognized and appreciated that ions may help provide highly stable and accurate atomic clocks because of their insensitivity to the environment and long trapping lifetimes. In high SWaP laboratory environments, using ions has achieved an inaccuracy below 3*10⁻¹⁸ and instability of 5*10⁻¹⁵ at 1 second by driving optical transitions. These systems rely on two high SWaP components: an ultra-stable laser for driving the transition and an octave spanning self-referenced frequency comb for down conversion to the microwave domain. Recently, lower SWaP ion clocks have been developed using a microwave transition in ¹⁷¹Yb⁺ with inaccuracy of 6*10⁻¹⁴ measured in 25 days and instability of 2*10⁻¹¹ at 1 second. By operating in the microwave domain, the complexity and SWaP are reduced compared to optical ion clocks at the cost of a factor of 10⁻⁴ in stability. Both approaches benefit from insensitivity to the environment of trapped-ion approaches, with the microwave approach achieving lower SWaP at the cost of stability.

The inventors have recognized and appreciated that neutral atom optical lattice clocks may achieve slightly better accuracy of 2*10⁻¹⁸ inaccuracy and an improvement by a factor of 10 in stability with 2*10⁻¹⁶ instability at 1 second compared to laboratory ion optical clocks. The neutral atom clocks may share the same large SWaP ultra-stable laser and octave spanning self-referenced frequency comb as the ion optical clocks and include additional large SWaP components such as Zeeman slowers and high power optical lattice laser beams. CSAC devices, such as those discussed above, attempt to provide a low SWaP microwave neutral atom clock, but as discussed, they greatly sacrifice stability and accuracy.

The inventors have recognized and appreciated that an ion-based atomic clock according to some embodiments may provide a more accurate, more stable, and lower SWaP clock for timing. Some embodiments may provide higher precision timing than previous clocks by offering a 1000-fold performance increase over previous clocks in a deployable a low SWaP package. For example, some embodiments may improve stability at 1 second by 1000 times as compared to existing low SWaP microwave based ion clocks and 10,000 times as compared to CSAC devices. The inventors have also recognized and appreciated that an ion-based atomic clock according to some embodiments may improve accuracy by 10 times compared to existing microwave ion clocks and by 10,000 times compared to CSAC devices. In some embodiments, stability may be comparable to laboratory grade ion optical clocks while being fieldable in a battery-operated low SWaP package that may fit in a person's hand. Additionally, some embodiments may improve timing in noisy environments, while also improving GPS signal capture, and providing holdover between intermittent GPS readings.

The inventors have recognized and appreciated that an ion-based atomic clock according to some embodiments may achieve low SWaP in at least three ways. First, the inventors have recognized and appreciated that driving a terahertz transition as opposed to an optical transition (e.g., 500 terahertz) may enable the use of a low SWaP and mature micro-resonator-based frequency comb. In some embodiments, the micro-resonator-based frequency comb may be low complexity and low volume and may require only modest bandwidth (24-50 terahertz), and it may not require f-2f self-referencing (as laboratory optical clocks do), reducing power, volume, and complexity while increasing maturity of the technology. Moreover, driving a terahertz transition rather than a microwave transition (e.g., 10 gigahertz) may avoid the inaccuracy and instability of existing microwave-transition atomic clocks. Second, the inventors have recognized and appreciated that the micro-resonator-based frequency comb in some embodiments may serve both as an ion probe laser and a microwave clock output, thereby reducing SWaP by not requiring these in separate components. Third, the inventors have recognized and appreciated that some embodiments may be made by integrating low SWaP components, including a 6.3 cubic centimeter micro-resonator-based frequency comb, a 3.5-4.5 cubic centimeter mini-vacuum ion trap assembly including a 1 cubic centimeter magnet, and millimeter-scale optics, and may be integrated using robotic pick-and-place. The result may be a low 50 cubic centimeter integrated physics package.

The inventors have also recognized and appreciated that terahertz transitions in Ca⁺, Sr⁺, and Ba⁺ may offer increased transition frequency, which may translate to 100 to 1000 times better accuracy and stability than existing atomic clocks that attempt to be low SWaP. Additionally, the inventors have recognized and appreciated that such transitions may provide low temperature sensitivity and low-magnetic-field sensitivity, further improving the fieldability of some embodiments.

The inventors have also recognized and appreciated that some embodiments may improve performance in communication systems with demanding data rates and increased spectrum congestion. Alternatively or additionally, some embodiments may enable new time-dependent encryption algorithms.

The inventors have also recognized and appreciated that some embodiments may improve synchronization between system-of-systems components on distributed platforms. Alternatively or additionally, some embodiments may enable new applications previously unavailable, such as remote high resolution imagery for reconnaissance and astronomy and time-dependent encryption algorithms. Some embodiments may additionally aid in locating underground nuclear tests.

Some embodiments include an atomic ion clock in which the micro-resonator-based frequency comb directly drives a terahertz transition between metastable levels in trapped ions of the clock. For example, the clock may use terahertz transitions between ²D_{3/2} and ²D_{5/2} metastable levels in trapped ions including Ca⁺, Sr⁺, or Ba⁺ (e.g., ¹³⁷Ba⁺) using a compact frequency comb. In some embodiments, the micro-resonator-based frequency comb may directly drive a Raman transition. The inventors have recognized and appreciated that directly driving such transitions may provide significant simplification to the clock and thereby improve SWaP further. The inventors have also recognized and appreciated that driving the terahertz transition between metastable levels may provide increased stability as discussed herein. For example, metastable levels may include D levels that may decay after about 1 to 30 seconds. Additionally, the inventors have recognized and appreciated that such metastable levels may exist in Ca⁺, Sr⁺, and Ba⁺ but not in common alkali neutral atoms.

Examples of implementations are discussed below, but it should be appreciated that embodiments are not limited to operating in accordance with any of these illustrative embodiments, as other embodiments are possible. Further, it should be appreciated that while some embodiments are described as being fieldable or deployable, embodiments are not limited to being implemented with any particular form of vehicle or structure.

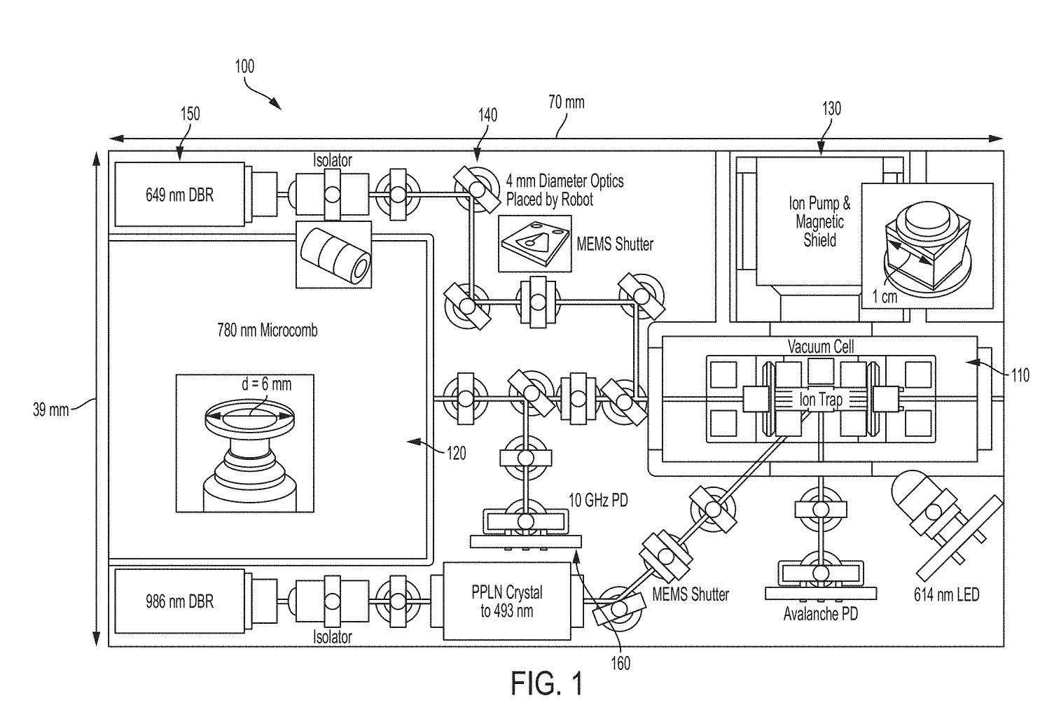

FIG. 1 shows an exemplary atomic clock apparatus 100 according to some embodiments. Apparatus 100 may include an ion trap 110, which may trap ions as discussed herein. Ion trap 110 may, in some embodiments, be a mini-vacuum ion trap assembly 110.

Additionally, apparatus 100 may include a frequency comb 120, which may be a micro-resonator-based frequency comb. In some embodiments, frequency comb 120 may have a repetition rate in the microwave domain (e.g., gigahertz) and may have sufficient bandwidth to span a terahertz transition.

According to some embodiments, frequency comb 120 may directly drive a terahertz transition between metastable levels in the trapped ions. For example, in some embodiments, frequency comb 120 may directly drive a 24 terahertz transition in at least one Ba⁺ ion. Alternatively, frequency comb 120 may directly drive a 8.4 terahertz transition in at least one Sr⁺ ion. Alternatively, frequency comb 120 may directly drive a 1.8 terahertz transition in at least one Ca⁺ ion.

According to some embodiments, during the driving process, a large (few thousand) multiple of the repetition frequency of frequency comb 120 may drive the ions' terahertz transition, and the difference between the (multiplied) comb frequency and the ions' transition frequency may be measured. Additionally, this measurement may be used to steer the repetition frequency of frequency comb 120 to track that of the ion and may transfer the stability of the ions' transition to the repetition frequency of frequency comb 120. According to some embodiments, the repetition rate may be detected and may serve as a microwave clock output 160 of apparatus 100. In some embodiments, frequency comb 120 may provide direct microwave output via microwave clock output 160. For example, the microwave output may be at 10 gigahertz with stability referenced to the 24 terahertz transition.

The inventors have recognized and appreciated that driving a terahertz transition as opposed to a microwave transition (as existing approaches do), the stability of the microwave clock output 160 may be increased by a few thousand (e.g., the ratio of the terahertz transition to the repetition rate), which may achieve instability limited by the inaccuracy of the atomic transition frequency. In some embodiments, by locking to the terahertz transition, frequency comb 120's microwave clock output 160 may acquire the accuracy of the atomic transition.

According to some embodiments, apparatus 100 may be free of a carrier-offset-stabilized frequency comb. For example, although existing optical atomic clocks may require a carrier-offset-stabilized frequency comb, the inventors have recognized and appreciated that some embodiments may not require one.

The inventors have recognized and appreciated that in addition to the 1000-fold improvement in frequency stability enabled by frequency comb 120, some embodiments may achieve accuracy of 3*10⁻¹⁵ inaccuracy by being highly insensitive to the environment. As discussed in part herein, the inventors have recognized and appreciated that trapped ions as used by some embodiments may be insensitive to temperature changes, magnetic fields, acceleration, optical Stark shifts, and clock orientation relative to gravity, and they may have low re-trace error. The inventors have also recognized and appreciated that the atomic clock apparatus 100 may also be insensitive to laser light power fluctuations if the polarization of the micro-resonator-based frequency comb is tuned and may be insensitive to magnetic field changes due to using a first order magnetic field insensitive transition.

According to some embodiments, apparatus 100 may include an ion pump 130, which may include a magnetic shield.

According to some embodiments, apparatus 100 may include millimeter-scale optics components 140. For example, millimeter-scale optics components 140 may be about 4 millimeters in diameter, and in some embodiments may be placed by an automated system (such as a robotic system) or any other suitable system.

According to some embodiments, frequency comb 120 may provide output similar to a pulsed laser. Alternatively or additionally, frequency comb 120 may provide output similar to a near-infrared laser. In some embodiments, an output of frequency comb 120 may operate at 780 nanometers. According to some embodiments, the transition may have a differential alternating current Stark shift tunable to zero via polarization over a broad range of wavelengths, including mature and efficient distributed Bragg reflector lasers at 780 nanometers. For example, apparatus 100 may include at least one laser 150, such as a distributed Bragg reflector laser.

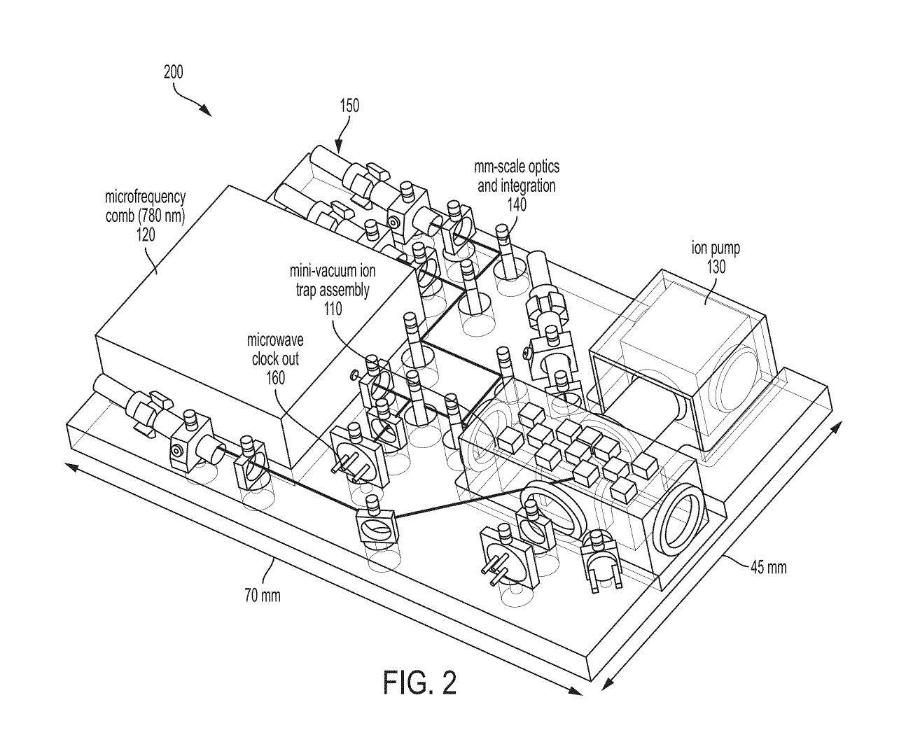

FIG. 2 is a perspective view of exemplary components of an exemplary atomic clock apparatus 100, in accordance with some embodiments. According to some embodiments, apparatus 100 may be small enough to fit in a person's hand. For example, apparatus 100 may have dimensions such as those shown in FIG. 2: 70 millimeters by 45 millimeters. Alternative, apparatus 100 may have dimensions such as those shown in FIG. 2: 70 millimeters by 39 millimeters. Some embodiments may be mounted on aircraft, including small unmanned aerial vehicles. Alternatively or additionally, apparatus 100 may be included in or connected to a computer or device for any of the applications described herein or any other suitable purpose.

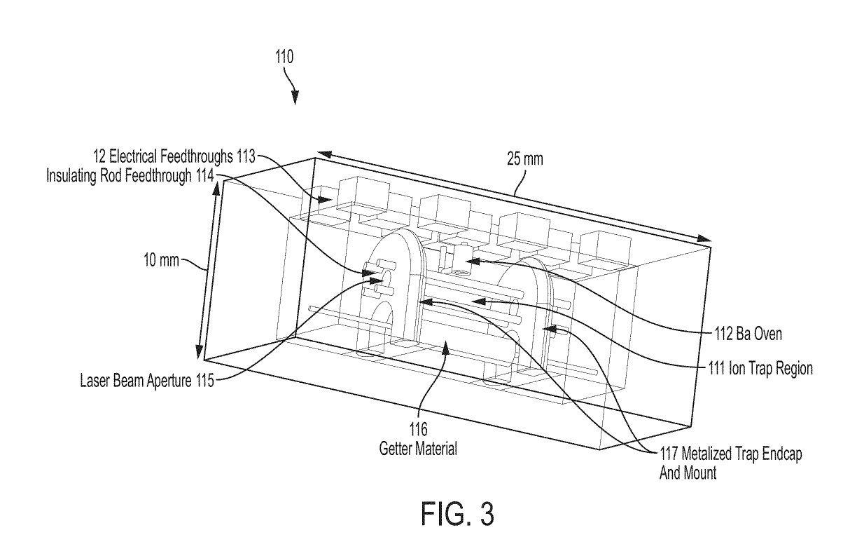

FIG. 3 is a perspective view of an exemplary ion trap 110, in accordance with some embodiments. As shown, according to some embodiments, ion trap 110 may be approximately 25 millimeters by 10 millimeters. In some embodiments, ion trap 110 may include ion trap region 111, in which ions may be located while trapped. Additionally, ion trap 110 may include a Ba oven 112 or any other suitable oven, which may be disposed above ion trap region 111. Ion trap 110 may also include electrical feedthroughs 113, which may be disposed above Ba oven 112 and may include 12 or any other suitable number of feedthroughs.

According to some embodiments, ion trap 110 may include at least one insulating rod feedthrough(s) 114, including four or any other number of feedthroughs. Additionally, ion trap 110 may include a laser beam aperture 115, which may be in between the insulating rod feedthrough(s) 114 and may intersect ion trap region 111. In some embodiments, ion trap 110 may include getter material 116, which may be disposed below ion trap region 111. Additionally, ion trap 110 may include metalized trap endcap and mount 117, which may be disposed on both ends of insulating rod feedthrough(s) 114.

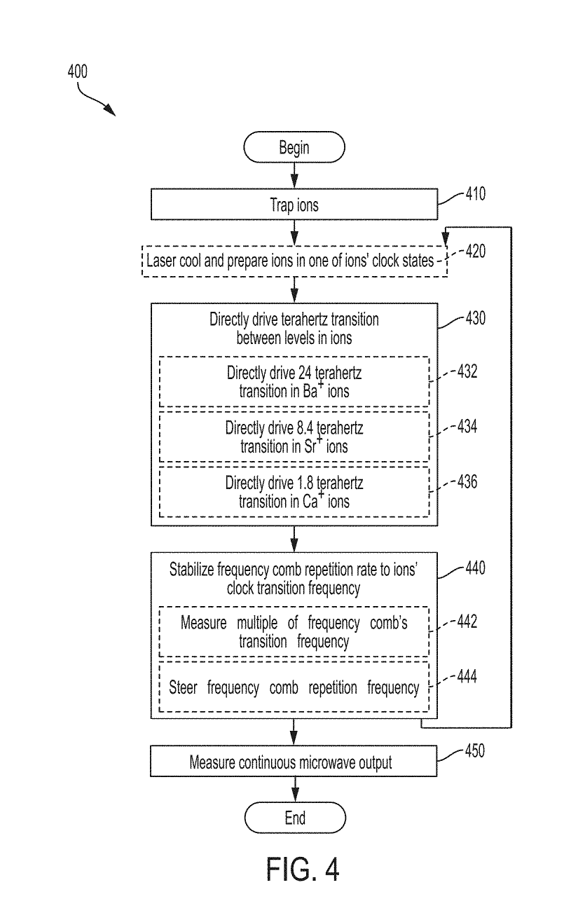

Referring now to FIG. 4, a flowchart of exemplary method of operation 400 of an exemplary atomic clock apparatus, which may be implemented by the system of FIG. 1 in some embodiments, is depicted.

At stage 410, ions may be trapped as discussed above. The method 400 may then optionally proceed to stage 420. At stage 420, ions may be laser cooled and prepared in one of the ions' clock states as discussed above. The method 400 may then proceed to stage 430.

At stage 430, a terahertz transition between levels (such as meta-stable levels) in ions may be directly driven, as discussed above. In some embodiments, stage 430 may include stage 432. At stage 432, a 24 terahertz transition in Ba⁺ ions may be directly driven. Alternatively, stage 430 may include stage 434. At stage 434, a 8.4 terahertz transition in Sr⁺ may be directly driven. Alternatively, stage 430 may include stage 436. At stage 436, a 1.8 terahertz transition in Ca⁺ may be directly driven. The method 400 may then proceed to stage 440.

At stage 440, the frequency comb repetition rate may be stabilized to the ions' clock transition frequency. In some embodiments, stage 440 may include stage 442. At stage 442, a multiple of the frequency comb's transition frequency may be measured by measuring the ions' transition probability. Additionally, stage 440 may include stage 444. At stage 444, the frequency comb repetition frequency may be steered such that the multiple matches the ions' transition frequency. In some embodiments, the method 400 may then proceed to both stages 450 and 420 continuously and in parallel.

At stage 450, the continuous microwave output may be measured (for example, on a photodetector such as microwave clock output 160). According to some embodiments, after stage 450 is executed the first time, stage 450 may continue to execute throughout the clock operation. Meanwhile, the sequence of stages 420, 430, and 440 may proceed in parallel, and once it finishes, it may update stage 450 and return to stage 420 again. Method 400 may end or repeat any desired number of times.

Having thus described several aspects of at least one embodiment of this application, it is to be appreciated that various alterations, modifications, and improvements will readily occur to those skilled in the art.

Such alterations, modifications, and improvements are intended to be part of this disclosure, and are intended to be within the spirit and scope of the application. Further, though advantages of the present application are indicated, it should be appreciated that not every embodiment will include every described advantage. Some embodiments may not implement any features described as advantageous herein and in some instances. Accordingly, the foregoing description and drawings are by way of example only.

Various aspects of the embodiments described above may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

The word “exemplary” is used herein to mean serving as an example, instance, or illustration. Any embodiment, implementation, process, feature, etc. described herein as exemplary should therefore be understood to be an illustrative example and should not be understood to be a preferred or advantageous example unless otherwise indicated.

Having thus described several aspects of at least one embodiment, it is to be appreciated that various alterations, modifications, and improvements will readily occur to those skilled in the art. Such alterations, modifications, and improvements are intended to be part of this disclosure, and are intended to be within the spirit and scope of the principles described herein. Accordingly, the foregoing description and drawings are by way of example only.

What is claimed is:

1. An ion-based atomic clock comprising:
an ion trap configured to trap a plurality of ions; and
a micro-resonator-based frequency comb configured to directly drive a terahertz transition between metastable levels in the trapped plurality of ions.

2. The ion-based atomic clock of claim 1, wherein:
the micro-resonator-based frequency comb is configured to directly drive a 24 terahertz transition in at least one Ba⁺ ion.

3. The ion-based atomic clock of claim 1, wherein:
the micro-resonator-based frequency comb is configured to directly drive a 8.4 terahertz transition in at least one Sr⁺ ion.

4. The ion-based atomic clock of claim 1, wherein:
the micro-resonator-based frequency comb is configured to directly drive a 1.8 terahertz transition in at least one Ca⁺ ion.

5. The ion-based atomic clock of claim 1, wherein:
the micro-resonator-based frequency comb is configured to provide output similar to a pulsed laser.

6. The ion-based atomic clock of claim 1, wherein:
the ion-based atomic clock is free of a carrier-offset-stabilized frequency comb.

7. The ion-based atomic clock of claim 1, further comprising:
a mini-vacuum ion trap assembly.

8. The ion-based atomic clock of claim 1, wherein:
polarization of the micro-resonator-based frequency comb is tuned to make the ion-based atomic clock be insensitive to laser light power fluctuations.

9. An apparatus comprising:
a micro-resonator-based frequency comb configured to directly drive a terahertz transition between metastable levels in a trapped plurality of ions.

10. The apparatus of claim 9, wherein:
the micro-resonator-based frequency comb is configured to directly drive a 24 terahertz transition in at least one Ba⁺ ion, a 8.4 terahertz transition in at least one Sr⁺ ion, or a 1.8 terahertz transition in at least one Ca⁺ ion.

11. The apparatus of claim 9, wherein:
the micro-resonator-based frequency comb is configured to provide output similar to a pulsed laser.

12. The apparatus of claim 9, wherein:
the ion-based atomic clock is free of a carrier-offset-stabilized frequency comb.

13. The apparatus of claim 9, further comprising:
a mini-vacuum ion trap assembly.

14. A method comprising:
trapping a plurality of ions; and
directly driving a terahertz transition between metastable levels in the trapped plurality of ions using a micro-resonator-based frequency comb.

15. The method of claim 14, wherein:
directly driving the terahertz transition comprises directly driving a 24 terahertz transition in at least one Ba⁺ ion.

16. The method of claim 14, wherein:
directly driving the terahertz transition comprises directly driving a 8.4 terahertz transition in at least one Sr⁺ ion.

17. The method of claim 14, wherein:
directly driving the terahertz transition comprises directly driving a 1.8 terahertz transition in at least one Ca⁺ ion.

18. The method of claim 14, further comprising:
providing output similar to a pulsed laser using the micro-resonator-based frequency comb.

19. The method of claim 14, wherein:
directly driving the terahertz transition comprises directly driving the terahertz transition without relying on a carrier-offset-stabilized frequency comb.

20. The method of claim 14, wherein:
polarization of the micro-resonator-based frequency comb is tuned to make the ion-based atomic clock be insensitive to laser light power fluctuations.
